(19) United States
(12) Patent Application Publication
(10) Pub. No.: US 2024/0396511 A1
(43) Pub. Date: Nov. 28, 2024

(54) ENERGY-EFFICIENT HYBRID AMPLIFIER ARCHITECTURE

(71) Applicant: MediaTek Singapore Pte. Ltd., Singapore (SG)

(72) Inventor: Takashi Kimura, Tokyo (JP)

(73) Assignee: MediaTek Singapore Pte. Ltd., Singapore (SG)

(21) Appl. No.: 18/666,830

(22) Filed: May 17, 2024

Related U.S. Application Data
(60) Provisional application No. 63/504,479, filed on May 26, 2023.

(51) Int. Cl. H03F 3/45; H03F 3/217

(52) U.S. Cl. CPC H03F 3/45475; H03F 3/2178; H03F 2203/45544

(57) ABSTRACT

The present invention provides an amplifier circuit including a primary stage and a secondary stage. The primary stage is configured to receive differential input signals to generate amplified signals, wherein the primary stage includes a first common mode feedback circuit configured to sense and control a common mode voltage of the amplified signals. The secondary stage is configured to receive the amplified signals to generate differential output signals, wherein the secondary stage includes a second common mode feedback circuit configured to sense and control a common mode voltage of the differential output signals.

### CROSS REFERENCE TO RELATED APPLICATIONS

This application claims the benefit of U.S. Provisional Application No. 63/504,479, filed on May 26, 2023. The content of the application is incorporated herein by reference.

### BACKGROUND

Amplifiers are commonly used components in circuit design and can be used in many different applications. For the amplifier design in a delta-sigma modulator, a single stage amplifier does not have sufficient loop gain, so a two-stage amplifier is considered to improve the loop gain. However, the two-stage amplifier may suffer a common mode dead-lock problem and the two-stage amplifier may also have poor settling performance due a time varying system. Therefore, how to design a stable two-stage amplifier with better performance is an important topic.

### SUMMARY

It is therefore an objective of the present invention to provide an amplifier circuit, which can avoid the common mode dead-lock issue and have better performance, to solve the above-mentioned problems.

According to one embodiment of the present invention, an amplifier circuit comprising a primary stage and a secondary stage is disclosed. The primary stage is configured to receive differential input signals to generate amplified signals, wherein the primary stage comprises a first common mode feedback circuit configured to sense and control a common mode voltage of the amplified signals. The secondary stage is coupled to the primary stage, configured to receive the amplified signals to generate differential output signals, wherein the secondary stage comprises a second common mode feedback circuit configured to sense and control a common mode voltage of the differential output signals.

According to one embodiment of the present invention, a floating inverter amplifier comprising a first inverter, a second inverter, a common mode feedback circuit, a first reservoir capacitor and a second reservoir capacitor is disclosed. The first inverter and the second inverter are configured to receive differential signals to generate differential output signals. The common mode feedback circuit is coupled to output terminals of the first inverter and the second inverter, and is configured to sense the common mode voltage of the differential output signals to generate a common mode feedback signal. The common mode feedback circuit generates the common mode feedback signal to control the first inverter and the second inverter through the first reservoir capacitor and the second reservoir capacitor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an amplifier circuit according to one embodiment of the present invention.

FIG. 2 is a diagram illustrating phases of a first clock signal and a second clock signal according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. The terms “couple” and “couples” are intended to mean either an indirect or a direct electrical connection. Thus, if a first device couples to a second device, that connection may be through a direct electrical connection, or through an indirect electrical connection via other devices and connections.

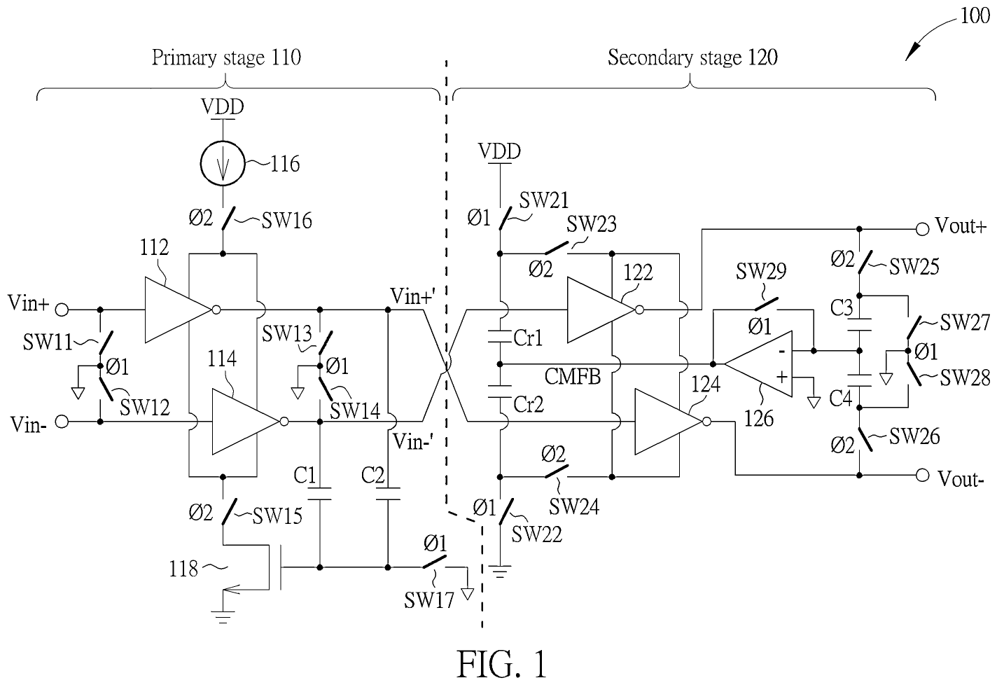

FIG. 1 is a diagram illustrating an amplifier circuit 100 according to one embodiment of the present invention. As shown in FIG. 1, the amplifier circuit 100 is a two-stage amplifier comprising a primary stage 110 and a secondary stage 120. In this embodiment, the amplifier circuit 100 can be applied to any application such as a delta-sigma modulator.

The primary stage 110 is an inverter-based amplifier, wherein the primary stage 110 is configured to receive differential input signals Vin+ and Vin− to generate amplified input signals Vin+′ and Vin−′. In this embodiment, the primary stage 110 comprises two inverters 112 and 114, a current source 116, a transistor 118, two capacitors C1 and C2, and a plurality of switches SW11-SW17. The inverter 112 is configured to receive the input signal Vin+′ to generate the amplified signal Vin+′, and the inverter 114 is configured to receive the input signal Vin− to generate the amplified signal Vin−′. An input terminal of the inverter 112 is selectively coupled to an input terminal of the inverter 114 via the switches SW11 and SW12, wherein a node between the switches SW11 and SW12 is coupled to a reference voltage such as a ground voltage. The current source 116 is a bias current source configured to provide a constant current to supply voltage nodes of the inverters 112 and 114 via the switch SW16, and ground voltage nodes of the inverters 112 and 114 is coupled to a ground voltage via the switch SW15 and the transistor 118. It is well known that the inverter has a PMOS and an NMOS connected together, and the supply voltage node can be a source electrode of the PMOS, and the ground voltage node can be a source electrode of the NMOS. A first node of the capacitor C1 is coupled to an output terminal of the inverter 114, and a second node of the capacitor C1 is coupled to a gate electrode of the transistor 118 and selectively coupled to the reference voltage via the switch SW17. A first node of the capacitor C2 is coupled to an output terminal of the inverter 112, and a second node of the capacitor C2 is coupled to the gate electrode of the transistor 118 and selectively coupled to the reference voltage via the switch SW17. In addition, the output terminal of the inverter 112 is selectively coupled to the output terminal of the inverter 114 via the switches SW13 and SW14, wherein a node between the switches SW13 and SW14 is coupled to a reference voltage such as the ground voltage.

The capacitors C1 and C2 serve as a common mode feedback circuit configured to sense the common mode voltage of the amplified input signals Vin+′ and Vin−′, and to feed it back to the inverters 112 and 114 via the transistor 118 to fix the DC components of the amplified input signals Vin+′ and Vin−′ to a desired level.

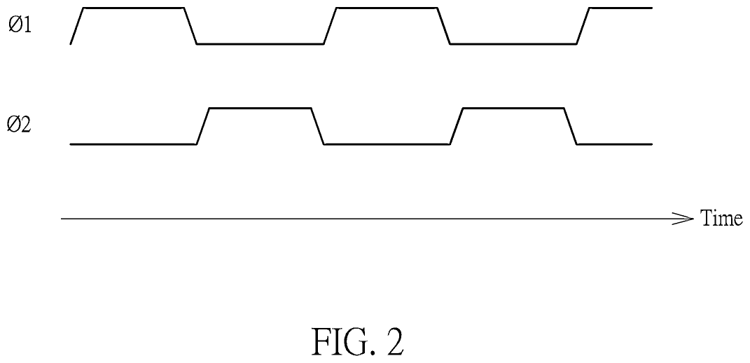

The switches SW11, SW12 SW13, SW14 and SW17 are controlled by a first clock signal with a phase ϕ1, and the switches SW15 and SW16 are controlled by a second clock signal with a phase ϕ2 as shown in FIG. 2, wherein the first clock signal and the second clock signal have inverting phases, that is the first clock signal and the second clock signal not do enable the corresponding switches simultaneously.

The secondary stage 120 is a floating inverter amplifier, wherein the secondary stage 120 is configured to receive the amplified input signals Vin+′ and Vin−′ to generate differential output signals Vout+ and Vout−. The secondary stage 120 comprises two inverters 122 and 124, two reservoir capacitors Cr1 and Cr2, a plurality of switches SW21-SW24 and a common mode feedback circuit, wherein the common mode feedback circuit comprises a comparator 126, two capacitors C3 and C4, and a plurality of switches SW25-SW29. The inverter 122 is configured to receive the amplified input signal Vin−′ to generate the output signal Vout+, and the inverter 124 is configured to receive the amplified input signal Vin+′ to generate the output signal Vout−. A first node of the reservoir capacitor Cr1 is selectively coupled to a supply voltage VDD via the switch SW21, and is also selectively coupled to supply voltage nodes of the inverters 122 and 124 via the switch SW23; and a second node of the reservoir capacitor Cr1 is configured to receive a common mode feedback signal CMFB generated by the comparator 126 of the common mode feedback circuit. A first node of the reservoir capacitor Cr2 is coupled to the second node of the reservoir capacitor Cr1, and the first node of the reservoir capacitor Cr2 is configured to receive the common mode feedback signal CMFB generated by the comparator 126 of the common mode feedback circuit. A second node of the reservoir capacitor Cr2 is selectively coupled to the ground voltage via the switch SW22, and is also selectively coupled to ground voltage nodes of the inverters 122 and 124 via the switch SW24.

Regarding the common mode feedback circuit of the secondary stage 120, a first node of the capacitor C3 is selectively coupled to the output signal Vout+ via the switch SW25, a second node of the capacitor C3 is coupled to a first node of the capacitor C4, and a second node of the capacitor C4 is selectively coupled to the output signal Vout− via the switch SW26. In addition, the first node of the capacitor C3 is selectively coupled to the second node of the capacitor C4 via the switches SW27 and SW28. The capacitors C3 and C4 are configured to sense the common mode voltage of the output signals Vout+ and Vout−, and the comparator 126 compares the sensed common mode voltage with a reference voltage to generate the common mode feedback signal CMFB to the second node of the reservoir capacitor Cr1 and the first node of the reservoir capacitor Cr2.

The switches SW21, SW22, SW27, SW28 and SW29 are controlled by the first clock signal with the phase ϕ1, and the switches SW23, SW24, SW25 and SW26 are controlled by the second clock signal with the phase ϕ2 as shown in FIG. 2, wherein the first clock signal and the second clock signal have inverting phases, that is the first clock signal and the second clock signal do not enable the corresponding switches simultaneously.

The amplifier circuit 100 operates with a first phase and a second phase. During the first phase, the first clock signal with ϕ1 enables the corresponding switches SW11, SW12, SW13, SW14, SW17, SW21, SW22, SW27, SW28 and SW29, and the second clock signal with ϕ2 disables the corresponding switches SW15, SW16, SW23, SW24, SW25 and SW26. In the first phase, the primary stage 110 is reset by connecting the input/output terminals to the reference voltage; and the secondary stage 120 is reset by connecting the reservoir capacitor Cr1 to the supply voltage VDD, connecting the reservoir capacitor Cr2 to the ground voltage, and connecting the capacitors C3 and C4 to the reference voltage. During the second phase, the first clock signal with ϕ1 disables the corresponding switches SW11, SW12, SW13, SW14, SW17, SW21, SW22, SW27, SW28 and SW29, and the second clock signal with ϕ2 enables the corresponding switches SW15, SW16, SW23, SW24, SW25 and SW26. In the second phase, the primary stage 110 receives the differential input signals Vin+ and Vin− to generate the amplified input signals Vin+′ and Vin−′, and the secondary stage 120 receives the amplified input signals Vin+′ and Vin−′ to generate differential output signals Vout+ and Vout−.

Regarding to the reservoir capacitors Cr1 and Cr2, in the first phase, the secondary stage is 120 reset, the first node of the reservoir capacitor Cr1 is coupled to the supply voltage, the first node of the reservoir capacitor Cr1 is not coupled to the supply voltage nodes of the inverters 122 and 124, the second node of the reservoir capacitor Cr2 is coupled to the ground voltage, and the second node of the reservoir capacitor Cr2 is not coupled to the ground voltage nodes of the inverters 122 and 124; and in the second phase, the first node of the reservoir capacitor Cr1 is not coupled to the supply voltage, the first node of the reservoir capacitor Cr1 is coupled to the supply voltage nodes of the inverters 122 and 124, the second node of the reservoir capacitor Cr2 is not coupled to the ground voltage, and the second node of the reservoir capacitor Cr2 is coupled to the ground voltage nodes of the inverters 122 and 124.

In the amplifier circuit 100 shown in FIG. 1, because the primary stage 110 and the secondary stage 120 has its own common feedback circuit, and the primary stage 110 does not receive or use the common mode feedback signal CMFB generated in the secondary stage 120, the amplifier circuit 100 will not suffer the common mode dead-lock issue. Specifically, in the conventional art, the primary stage uses the common mode feedback signal generated in the secondary stage, so if the common mode voltage of the output signals goes high, the common mode voltage of the input signals of the primary stage also becomes high, then the common mode voltage of the amplified signals generated by the primary stage may be still at low voltage level to make the output signals have high common mode voltage. Therefore, the output signals of the amplifier circuit of the prior art will be locked and cannot be recovered unless the amplifier circuit is reset. The architecture of the amplifier circuit 100 can solve this problem.

In this embodiment, the reservoir capacitors Cr1 and Cr2 serve as a compensation capacitor to make the common mode voltage of the output signals Vout+ and Vout− be controlled well. Specifically, the conventional floating inverter amplifier has a self-aligned common mode voltage, however, this self-aligned common mode voltage cannot be controlled well because the primary stage defines the common mode voltage of the amplified input signals Vin+′ and Vin−′. Therefore, by using the common mode feedback circuit to generate the common mode feedback signal CMFB to force the middle voltage of the reservoir capacitors Cr1 and Cr2, the common mode voltage of the output signals Vout+ and Vout− be controlled well to improve the performance.

In the embodiment shown in FIG. 1, by using the inverter-based amplifier with the bias current source and the common mode feedback circuit to implement the primary stage 110, the power consumption is decreased and the amplified input signals Vin+′ and Vin−′ may have low noise. In addition, the secondary stage 120 may have better driving ability by using the floating inverter amplifier with the common mode feedback circuit.

It is noted that the detailed circuits of the common mode feedback circuit of the primary circuit and the common mode feedback circuit of the secondary circuit are for illustrative, not a limitation of the present invention.

In another embodiment, the primary stage 110 can be replaced by any other suitable amplifier stage. This alternative design shall fall within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplifier circuit, comprising:
a primary stage, configured to receive differential input signals to generate amplified signals, wherein the primary stage comprises a first common mode feedback circuit configured to sense and control a common mode voltage of the amplified signals; and
a secondary stage, coupled to the primary stage, configured to receive the amplified signals to generate differential output signals, wherein the secondary stage comprises a second common mode feedback circuit configured to sense and control a common mode voltage of the differential output signals.

2. The amplifier circuit of claim 1, wherein the primary stage is an inverter-based amplifier, and the primary stage comprises:
a first inverter and a second inverter, configured to receive the differential input signals to generate the amplified signals, respectively; and
the first common mode feedback circuit, coupled to output terminals of the first inverter and the second inverter, configured to sense and control the common mode voltage of the amplified signals.

3. The amplifier circuit of claim 2, wherein primary stage further comprises:
a current source, configured to provide a current to supply voltage nodes of the first inverter and the second inverter; and
a transistor, configured to selectively connect ground voltage nodes of the first inverter and the second inverter to a ground voltage;
wherein the first common mode feedback circuit senses the common mode voltage of the differential output signals, and feeds the common mode voltage of the differential output signals back to a gate electrode of the transistor.

4. The amplifier circuit of claim 3, wherein the current source is a bias current source configured to provide a constant current to the supply voltage nodes of the first inverter and the second inverter.

5. The amplifier circuit of claim 1, wherein the secondary stage is a floating inverter amplifier, and the secondary stage comprises:
a third inverter and a fourth inverter, configured to receive the amplified signals to generate the differential output signals;
the second common mode feedback circuit, coupled to output terminals of the third inverter and the fourth inverter, configured to sense the common mode voltage of the differential output signals to generate a common mode feedback signal; and
a first reservoir capacitor and a second reservoir capacitor, wherein the second common mode feedback circuit generates the common mode feedback signal to control the third inverter and the fourth inverter through the first reservoir capacitor and the second reservoir capacitor.

6. The amplifier circuit of claim 5, wherein a first node of the first reservoir capacitor is coupled to a supply voltage, a second node of the first reservoir capacitor is coupled to a first node of the second reservoir capacitor, and a second node of the second reservoir capacitor is coupled to a ground voltage; and the second common mode feedback circuit generates the common mode feedback signal to the second node of the first reservoir capacitor.

7. The amplifier circuit of claim 6, wherein the first node of the first reservoir capacitor is selectively coupled to the supply voltage and supply voltage nodes of the third inverter and the fourth inverter; and the second node of the second reservoir capacitor is selectively coupled to the ground voltage and ground voltage nodes of the third inverter and the fourth inverter.

8. The amplifier circuit of claim 7, wherein the amplifier circuit operates in a first phase and a second phase; in the first phase, the secondary stage is reset, the first node of the first reservoir capacitor is coupled to the supply voltage, the first node of the first reservoir capacitor is not coupled to the supply voltage nodes of the third inverter and the fourth inverter, the second node of the second reservoir capacitor is coupled to the ground voltage, and the second node of the second reservoir capacitor is not coupled to the ground voltage nodes of the third inverter and the fourth inverter; and in the second phase, the first node of the first reservoir capacitor is not coupled to the supply voltage, the first node of the first reservoir capacitor is coupled to the supply voltage nodes of the third inverter and the fourth inverter, the second node of the second reservoir capacitor is not coupled to the ground voltage, and the second node of the second reservoir capacitor is coupled to the ground voltage nodes of the third inverter and the fourth inverter.

9. A floating inverter amplifier, comprising:
a first inverter and a second inverter, configured to receive differential signals to generate differential output signals;
a common mode feedback circuit, coupled to output terminals of the first inverter and the second inverter, configured to sense the common mode voltage of the differential output signals to generate a common mode feedback signal; and
a first reservoir capacitor and a second reservoir capacitor, wherein the common mode feedback circuit generates the common mode feedback signal to control the first inverter and the second inverter through the first reservoir capacitor and the second reservoir capacitor.

10. The floating inverter amplifier of claim 9, wherein a first node of the first reservoir capacitor is coupled to a supply voltage, a second node of the first reservoir capacitor is coupled to a first node of the second reservoir capacitor, and a second node of the second reservoir capacitor is coupled to a ground voltage; and the common mode feedback circuit generates the common mode feedback signal to the second node of the first reservoir capacitor.

11. The floating inverter amplifier of claim 10, wherein the first node of the first reservoir capacitor is selectively coupled to the supply voltage and supply voltage nodes of the first inverter and the second inverter; and the second node of the second reservoir capacitor is selectively coupled to the ground voltage and ground voltage nodes of the first inverter and the second inverter.

12. The floating inverter amplifier of claim 11, wherein the floating inverter amplifier operates in a first phase and a second phase; in the first phase, the floating inverter amplifier is reset, the first node of the first reservoir capacitor is coupled to the supply voltage, the first node of the first reservoir capacitor is not coupled to the supply voltage nodes of the first inverter and the second inverter, the second node of the second reservoir capacitor is coupled to the ground voltage, and the second node of the second reservoir capacitor is not coupled to the ground voltage nodes of the first inverter and the second inverter; and in the second phase, the first node of the first reservoir capacitor is not coupled to the supply voltage, the first node of the first reservoir capacitor is coupled to the supply voltage nodes of the first inverter and the second inverter, the second node of the second reservoir capacitor is not coupled to the ground voltage, and the second node of the second reservoir capacitor is coupled to the ground voltage nodes of the first inverter and the second inverter.
